(19) United States
(12) Patent Application Publication
(10) Pub. No.: US 2023/0357558 A1
(43) Pub. Date: Nov. 9, 2023

(54) RESIN COMPOSITION, PREPREG USING SAME, FILM PROVIDED WITH RESIN, METAL FOIL PROVIDED WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Yiqun WANG, Osaka (JP); Hirosuke SAITO, Osaka (JP); Hiroharu INOUE, Osaka (JP)

(73) Assignee: PANASONIC INTELLECTUAL PROPERTY MANAGEMENT CO., LTD., Osaka (JP)

(21) Appl. No.: 18/026,292

(22) PCT Filed: Sep. 10, 2021
(86) PCT No.: PCT/JP2021/033408

§ 371 Date: Mar. 14, 2023

(30) Foreign Application Priority Data
Sep. 18, 2020 (JP) 2020-157403

(51) Int. Cl. C08L 53/00; C08G 65/48; C08K 5/14; C08K 7/18; C08J 5/24; C08J 7/04; H05K 1/03

(52) U.S. Cl. CPC C08L 53/00; C08G 65/485; C08K 5/14; C08K 7/18; C08J 5/244; C08J 7/0427; H05K 1/0353; C08J 2353/00; C08L 2203/16; C08L 2203/20

(57) ABSTRACT

A resin composition contains a styrenic block copolymer, a radical polymerizable compound, and at least one free radical compound selected from the group consisting of a compound (A) represented by Formula (1), a compound (B) represented by Formula (2), and a compound (C) having two or more of at least one group selected from groups represented by Formulas (3-1) and (3-2).

### TECHNICAL FIELD

The present invention relates to a resin composition, and a prepreg, a film with resin, a metal foil with resin, a metal-clad laminate, and a wiring board obtained using the resin composition.

### BACKGROUND ART

In recent years, in various electronic devices, mounting technologies such as higher integration of semiconductor devices to be mounted, higher wiring density, and multi-layering have rapidly progressed along with an increase in the amount of information processed. Substrate materials for forming base materials of wiring boards used in various electronic devices are required to have a low dielectric constant and a low dielectric loss tangent to increase the transmission speed of signals and decrease the loss during signal transmission.

It is known that polyphenylene ether (PPE) exhibits excellent dielectric properties such as a low dielectric constant and a low dielectric loss tangent and exhibits excellent dielectric properties such as dielectric constant and dielectric loss tangent in a high frequency band (high frequency region) from the MHz band to the GHz band as well. For this reason, it has been investigated that polyphenylene ether is used, for example, as a high frequency molding material. More specifically, polyphenylene ether is preferably used as a substrate material for forming a base material of a wiring board to be equipped in electronic equipment utilizing a high frequency band.

For example, Patent Literature 1 discloses a resin composition containing a modified polyphenylene ether compound and a styrenic thermoplastic elastomer having a weight average molecular weight of 10000 or more.

According to a resin composition as disclosed in Patent Literature 1, it is reported that film forming ability can be imparted without impairing low dielectric properties and heat resistance.

Meanwhile, in recent years, superior low dielectric properties are required for substrate materials that are required to be further thinned. Hence, it is conceivable to increase the amount of styrenic thermoplastic elastomer added, but since the elastomer has a high molecular weight, if the content thereof is increased, there is a problem in circuit filling properties when the resin composition is used as a substrate material.

### CITATION LIST

### Patent Literature

Patent Literature 1: JP 2006-83364 A

### SUMMARY OF INVENTION

The present invention is made in view of such circumstances, and an object thereof is to provide a resin composition, which imparts properties such as excellent low dielectric properties, a low coefficient of thermal expansion, and a high Tg to its cured product and exhibits excellent circuit filling properties when used as a substrate material. Another object of the present invention is to provide a prepreg, a film with resin, a metal foil with resin, a metal-clad laminate, and a wiring board, which are obtained using the resin composition.

The resin composition according to an aspect of the present invention contains a styrenic block copolymer, a radical polymerizable compound, and at least one free radical compound selected from the group consisting of a compound (A) represented by the following Formula (1), a compound (B) represented by the following Formula (2), and a compound (C) having two or more of at least one group selected from groups represented by the following Formulas (3-1) and (3-2).

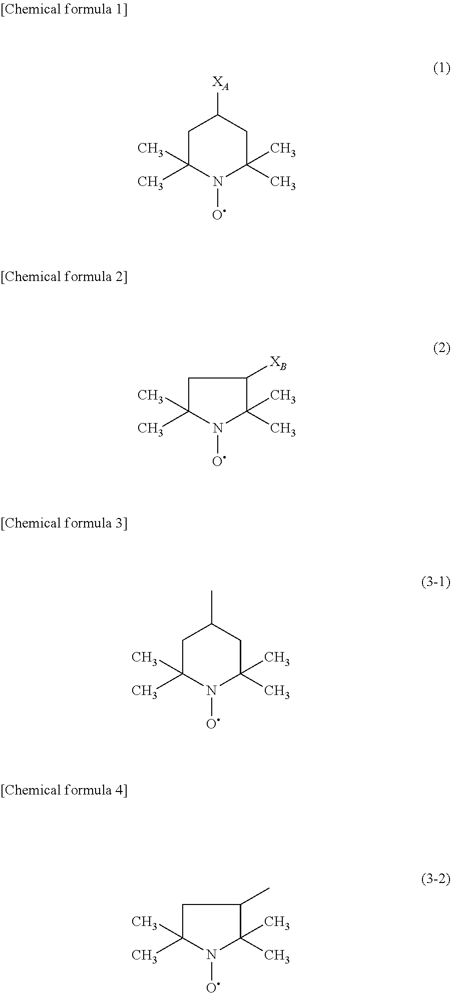

(In Formulas (1) and (2), X_{A} and X_{B} each independently represent a hydrogen atom, an amino group, a cyano group, a hydroxy group, an isothiocyanate, a methoxy group, a carboxy group, a carbonyl group, an amide group, or a benzoyloxy group.)

### BRIEF DESCRIPTION OF DRAWINGS

FIG. 1 is a schematic sectional view illustrating the configuration of a prepreg according to an embodiment of the present invention.

FIG. 2 is a schematic sectional view illustrating the configuration of a metal-clad laminate according to an embodiment of the present invention.

FIG. 3 is a schematic sectional view illustrating the configuration of a wiring board according to an embodiment of the present invention.

FIG. 4 is a schematic sectional view illustrating the configuration of a metal foil with resin according to an embodiment of the present invention.

FIG. 5 is a schematic sectional view illustrating the configuration of a resin film according to an embodiment of the present invention.

### DESCRIPTION OF EMBODIMENTS

The resin composition according to an embodiment of the present invention (hereinafter also simply referred to as a resin composition) contains a styrenic block copolymer, a radical polymerizable compound, and at least one free radical compound selected from the group consisting of a compound (A) represented by Formula (1), a compound (B) represented by Formula (2), and a compound (C) having two or more of at least one group selected from groups represented by Formulas (3-1) and (3-2).

By containing a styrenic block copolymer and a radical polymerizable compound, it is possible to obtain a resin composition, which imparts low dielectric properties, a low coefficient of thermal expansion, and a high Tg (glass transition temperature) to its cured product. Meanwhile, as a styrenic block copolymer is used, there is concern about deterioration in resin flowability when used as a resin composition or a semi-cured product (B stage) of the resin composition and circuit filling properties, but it is possible to delay the start of curing of the resin and lower the minimum melt viscosity by adding a free radical compound as in the present embodiment. Hence, it is considered that the circuit filling properties can be improved while maintaining low dielectric properties, a high Tg, and the like.

As for the material properties, a material imparting a high Tg to a cured product is one of the factors for further improvement in heat resistance (reflow heat resistance and the like). A material imparting a high Tg to a cured product has also the advantage that the coefficient of thermal expansion of the material is small in a higher temperature region. In general, since the thermal expansion increases rapidly at temperatures exceeding the glass transition temperature, the coefficient of thermal expansion increases in the high temperature region exceeding the glass transition temperature when the glass transition temperature is low. When the coefficient of thermal expansion in a high temperature region is large, for example, interlayer connection reliability (generation of barrel cracks in through-holes, and the like) in the wiring board deteriorates and there is a risk that the wiring board does not function as a printed board. It is considered that this is because the wall surface of the through-hole formed of metal cracks and the connection reliability deteriorates since the difference in coefficient of thermal expansion at high temperatures between the insulating layer formed of a cured product of the resin composition and the material of the through-hole formed of metal increases in the board.

In other words, according to the present invention, it is possible to provide a resin composition, which imparts properties such as excellent low dielectric properties, a low coefficient of thermal expansion, and a high Tg to its cured product and exhibits excellent circuit filling properties when used as a substrate material. By using the resin composition, it is possible to provide a prepreg, a film with resin, a metal foil with resin, a metal-clad laminate, and a wiring board which exhibit the excellent properties.

Hereinafter, the respective components of the resin composition according to the present embodiment will be specifically described.

(Styrenic Block Copolymer)

The resin composition of the present embodiment contains a styrenic block copolymer. Therefore, it is considered that there are advantages such as a further decrease in dielectric constant of the resin and improvement in handleability (film properties) when a resin composition or a semi-cured product (B stage) of the resin composition is prepared.

The styrenic block copolymer used in the present embodiment is, for example, a copolymer obtained by block-polymerizing monomers including a styrenic monomer. Examples of the styrenic copolymer include a copolymer obtained by block-polymerizing one or more styrenic monomers and one or more other monomers copolymerizable with the styrenic monomers. Examples of the styrenic monomers include styrene and styrene derivatives.

The weight average molecular weight of the styrenic block copolymer of the present embodiment is preferably about 10,000 to 200,000, more preferably about 50,000 to 180,000. When the weight average molecular weight is in the above range, there is an advantage that it is possible to ensure appropriate resin fluidity in the resin composition or a semi-cured state (B stage) of the resin composition. In the present specification, the weight average molecular weight may be measured by a general molecular weight measurement method, and specific examples thereof include a value measured by gel permeation chromatography (GPC).

In a preferred embodiment, the styrenic block copolymer of the present embodiment is preferably a styrenic block copolymer having a hardness of 20 to 100. Furthermore, the hardness of the styrenic block copolymer is preferably 30 to 80. By containing a styrenic block copolymer of which the hardness is in the above range, it is considered that a resin composition is obtained which becomes a cured product exhibiting lower dielectric properties and a lower coefficient of thermal expansion when cured.

The hardness includes, for example, durometer hardness, more specifically durometer hardness measured using a type A durometer conforming to JIS K 6253.

As a specific styrenic block copolymer, conventionally known ones can be widely used, the styrenic block copolymer is not particularly limited, and examples thereof include a polymer having a structural unit represented by the following Formula (5) (a structure derived from a styrenic monomer) in the molecule.

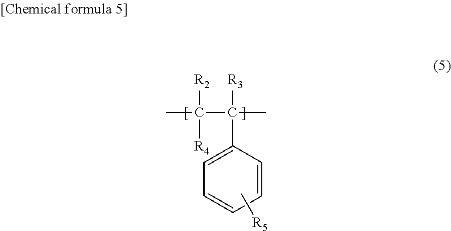

In Formula (5), R₂ to R₄ each independently represent a hydrogen atom or an alkyl group, and R₅ represents a hydrogen atom, an alkyl group, an alkenyl group, or an isopropenyl group. The alkyl group is not particularly limited and is, for example, preferably an alkyl group having 1 to 18 carbon atoms and more preferably an alkyl group having 1 to 10 carbon atoms. The alkenyl group is preferably an alkenyl group having 1 to 10 carbon atoms. Specific examples thereof include a methyl group, an ethyl group, a propyl group, a hexyl group, and a decyl group.

The styrenic block copolymer of the present embodiment preferably contains at least one structural unit represented by Formula (5), but may contain two or more different structural units in combination. The styrenic block copolymer may contain a structure in which the structural unit represented by Formula (5) is repeated.

The styrenic block copolymer of the present embodiment may have at least one among structural units represented by the following Formulas (6) to (8) as another monomer copolymerizable with the styrenic monomer in addition to the structural unit represented by Formula (5).

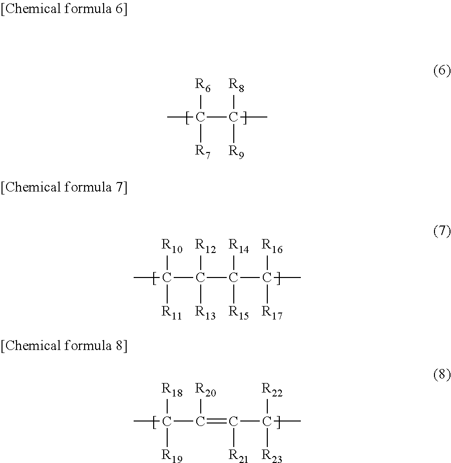

In Formulas (6) to (8), R₆ to R₂₃ each independently represent any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. The alkenyl group is preferably an alkenyl group having 1 to 10 carbon atoms. Specific examples thereof include a methyl group, an ethyl group, a propyl group, a hexyl group, and a decyl group. The styrenic block copolymer of the present embodiment preferably contains at least one among the structural units represented by Formulas (6) to (8), and may contain two or more different structural units among these in combination. The styrenic block copolymer may contain a structure in which the structural units represented by Formulas (6), (7) and/or (8) are repeated.

More specific examples of the structural unit represented by Formula (5) include structural units represented by the following Formulas (9) to (11). The structural unit represented by Formula (5) may be one structural unit among these or a combination of two or more different structural units. The structural unit represented by Formula (5) may also be a structure in which the structural units represented by Formulas (9) to (11) are each repeated.

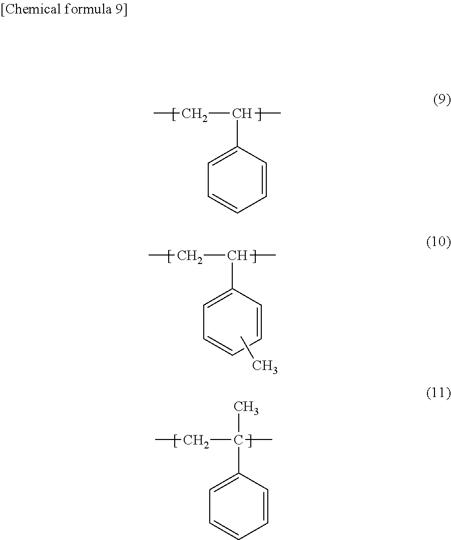

More specific examples of the structural unit represented by Formula (6) include structural units represented by the following Formulas (12) to (18). The structural unit represented by Formula (6) may be one structural unit among these or a combination of two or more different structural units. The structural unit represented by Formula (6) may also be a structure in which the structural units represented by Formulas (12) to (18) are each repeated.

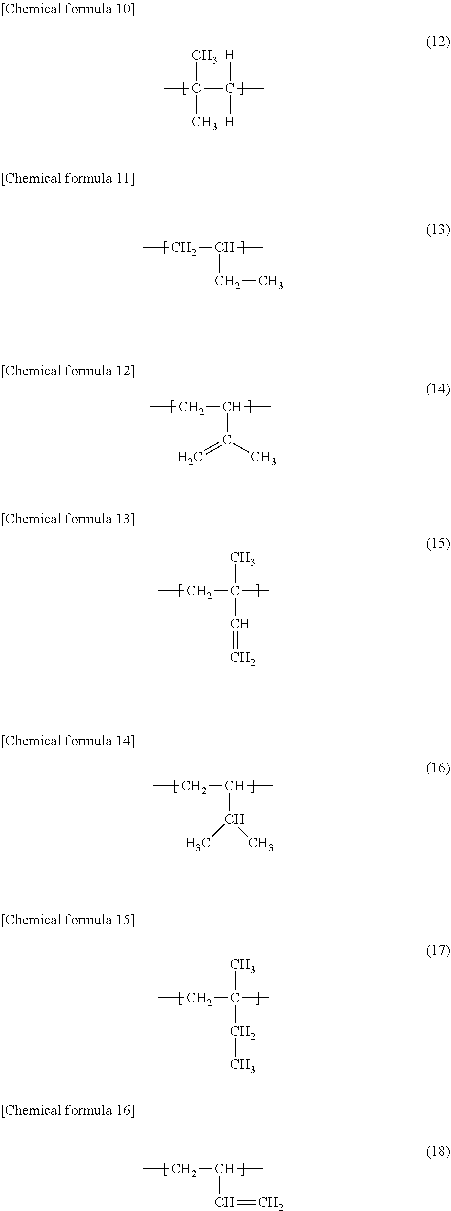

More specific examples of the structural unit represented by Formula (7) include structural units represented by the following Formulas (19) and (20). The structural unit represented by Formula (7) may be one structural unit among these or a combination of two or more different structural units. The structural unit represented by Formula (7) may also be a structure in which the structural units represented by Formulas (19) and (20) are each repeated.

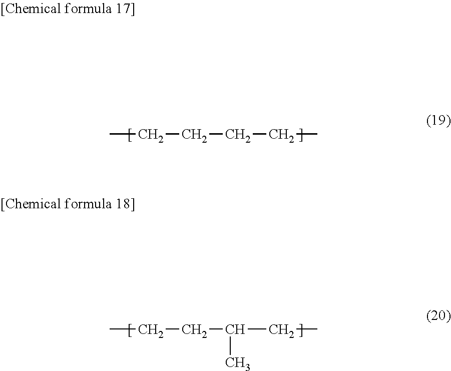

More specific examples of the structural unit represented by Formula (8) include structural units represented by the following Formulas (21) and (22). The structural unit represented by Formula (8) may be one structural unit among these or a combination of two or more different structural units. The structural unit represented by Formula (8) may also be a structure in which the structural units represented by Formulas (21) and (22) are each repeated.

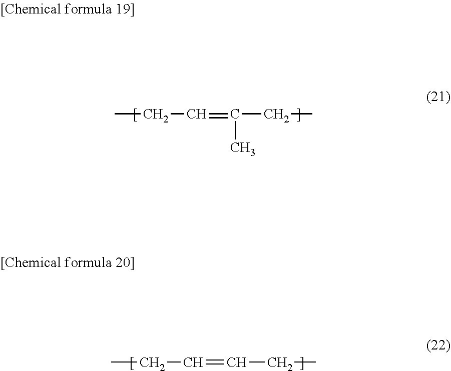

Preferred examples of the styrenic block copolymer include copolymers obtained by polymerizing or copolymerizing one or more styrenic monomers such as styrene, styrene ethylene, vinyltoluene, α-methylstyrene, isopropenyltoluene, divinylbenzene, or allylstyrene. More specific examples thereof include a methylstyrene (ethylene/butylene) methylstyrene copolymer, a methylstyrene (ethylene-ethylene/propylene) methylstyrene copolymer, a styrene isoprene copolymer, a styrene isoprene styrene copolymer, a styrene (ethylene/butylene) styrene copolymer, a styrene (ethylene-ethylene/propylene) styrene copolymer, a styrene butadiene styrene copolymer, a styrene (butadiene/butylene) styrene copolymer, and a styrene isobutylene styrene copolymer, and hydrogenated products thereof.

As the styrenic block copolymer, those exemplified above may be used singly or in combination of two or more kinds thereof.

In a case where the styrenic block copolymer contains at least one among the structural units represented by Formulas (9) to (11), the mass fraction (namely, the content of the structural unit derived from styrene) is preferably about 10% to 60%, more preferably about 20% to 40% with respect to the entire polymer. Therefore, there is an advantage that superior dielectric properties are also attained when the resin composition is cured while favorable compatibility with the radical polymerizable compound is maintained.

As the styrenic block copolymer of the present embodiment, commercially available products can also be used, and examples thereof include “SEPTON V9827” and “SEPTON 2063” manufactured by Kuraray Co., Ltd., “Tuftec (registered trademark) H1052”, “Tuftec (registered trademark) H1041” and “Tuftec (registered trademark) H1221” manufactured by Asahi Kasei Corporation, and “Dynaron 9901P” manufactured by JSR Corporation.

<Radical Polymerizable Compound>

The radical polymerizable compound used in the present embodiment is not particularly limited as long as it is a compound exhibiting radical polymerizability, but it is preferable to contain a polyphenylene ether compound of which the terminal is modified with a substituent having a carbon-carbon unsaturated double bond.

The polyphenylene ether compound that can be used in the present embodiment is preferably a modified polyphenylene ether compound that can exert excellent low dielectric properties when cured, and is preferably a polyphenylene ether compound having a group represented by the following Formula (4). It is considered that a resin composition, which can afford a cured product exhibiting low dielectric properties and high heat resistance, is obtained by containing such a modified polyphenylene ether compound.

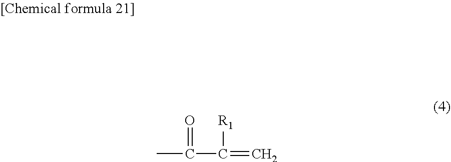

In Formula (4), R₁ represents a hydrogen atom or an alkyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Alternatively, the polyphenylene ether compound of the present embodiment may be a polyphenylene ether compound having a group represented by the following Formula (23).

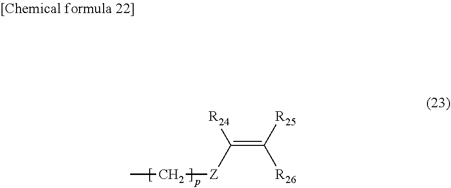

In Formula (23), p represents an integer 0 to 10. Z represents an arylene group. R₁ to R₃ are independent of each other. In other words, R₂₄ to R₂₆ may be the same group as or different groups from each other. R₂₄ to R₂₆ represent a hydrogen atom or an alkyl group.

In a case where p in Formula (23) is 0, it indicates that Z is directly bonded to the terminal of polyphenylene ether.

The arylene group of Z is not particularly limited. Examples of this arylene group include a monocyclic aromatic group such as a phenylene group, and a polycyclic aromatic group in which the aromatic is not a single ring but a polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group. In addition, the alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Examples of the substituent represented by Formula (4) include an acrylate group and a methacrylate group. Preferred specific examples of the substituent represented by Formula (23) include, for example, a substituent having a vinylbenzyl group. Examples of the substituent having a vinylbenzyl group include a substituent represented by the following Formula (24).

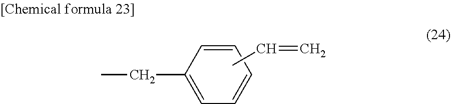

More specific examples of the substituent include vinylbenzyl groups (ethenylbenzyl groups) such as a p-ethenylbenzyl group and an m-ethenylbenzyl group, a vinylphenyl group, an acrylate group, and a methacrylate group.

The polyphenylene ether compound has a polyphenylene ether chain in the molecule and preferably has, for example, a repeating unit represented by the following Formula (25) in the molecule.

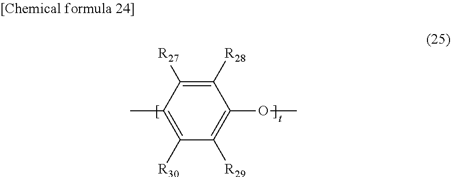

In Formula (25), t represents 1 to 50. R₂₇ to R₃₀ are independent of each other. In other words, R₂₇ to R₃₀ may be the same group as or different groups from each other. R₂₇ to R₃₀ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₂₇ to R₃₀ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) of the polyphenylene ether compound is not particularly limited. Specifically, the weight average molecular weight is preferably 500 to 5000, more preferably 800 to 4000, and still more preferably 1000 to 3000. The weight average molecular weight may be measured by a general molecular weight measurement method, and specific examples thereof include a value measured by gel permeation chromatography (GPC). In a case where the polyphenylene ether compound has a repeating unit represented by Formula (25) in the molecule, t is preferably a numerical value so that the weight average molecular weight of the polyphenylene ether compound is in such a range. Specifically, t is preferably 1 to 50.

When the weight average molecular weight of the polyphenylene ether compound is in such a range, the polyphenylene ether compound exhibits the excellent low dielectric properties of polyphenylene ether and not only imparts superior heat resistance to the cured product but also exhibits excellent moldability. This is considered to be due to the following. When the weight average molecular weight of ordinary polyphenylene ether is in such a range, the heat resistance of the cured product tends to decrease since the molecular weight is relatively low. With regard to this point, since the polyphenylene ether compound according to the present embodiment has one or more unsaturated double bonds at the terminal, it is considered that a cured product exhibiting sufficiently high heat resistance is obtained. When the weight average molecular weight of the polyphenylene ether compound is within such a range, the polyphenylene ether compound has a relatively low molecular weight and is thus considered to exhibit excellent moldability as well. Hence, it is considered that such a polyphenylene ether compound not only imparts superior heat resistance to the cured product but also exhibits excellent moldability.

In the polyphenylene ether compound, the average number of the substituents (number of terminal functional groups) at the molecule terminal per one molecule of the polyphenylene ether compound is not particularly limited. Specifically, the average number is preferably 1 to 5, more preferably 1 to 3, and still more preferably 1.5 to 3. When the number of terminal functional groups is too small, sufficient heat resistance of the cured product tends to be hardly attained. When the number of terminal functional groups is too large, the reactivity is too high and, for example, troubles such as a decrease in in the storage stability of the resin composition or a decrease in the fluidity of the resin composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the modified polyphenylene ether compounds present in 1 mole of the polyphenylene ether compound. This number of terminal functional groups can be determined, for example, by measuring the number of hydroxyl groups remaining in the obtained modified polyphenylene ether compound and calculating the number of hydroxyl groups decreased from the number of hydroxyl groups in the polyphenylene ether before being modified. The number of hydroxyl groups decreased from the number of hydroxyl groups in the polyphenylene ether before being modified is the number of terminal functional groups. With regard to the method for measuring the number of hydroxyl groups remaining in the modified polyphenylene ether compound, the number of hydroxyl groups can be determined by adding a quaternary ammonium salt (tetraethylammonium hydroxide) to be associated with a hydroxyl group to a solution of the modified polyphenylene ether compound and measuring the UV absorbance of the mixed solution.

The intrinsic viscosity of the polyphenylene ether compound of the present embodiment is not particularly limited. Specifically, the intrinsic viscosity may be 0.03 to 0.12 dl/g, and is preferably 0.04 to 0.11 dl/g and more preferably 0.06 to 0.095 dl/g. When this intrinsic viscosity is too low, the molecular weight tends to be low and low dielectric properties such as a low dielectric constant and a low dielectric loss tangent tend to be unlikely attained. When the intrinsic viscosity is too high, the viscosity is high, sufficient fluidity is not attained, and the moldability of the cured product tends to decrease. Hence, when the intrinsic viscosity of the polyphenylene ether compound is in the above range, excellent heat resistance and moldability of the cured product can be realized.

Note that the intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound of the present embodiment include modified polyphenylene ether compounds represented by the following Formulas (26) to (28). Moreover, as the polyphenylene ether compound of the present embodiment, these modified polyphenylene ether compounds may be used singly or these modified polyphenylene ether compounds may be used in combination.

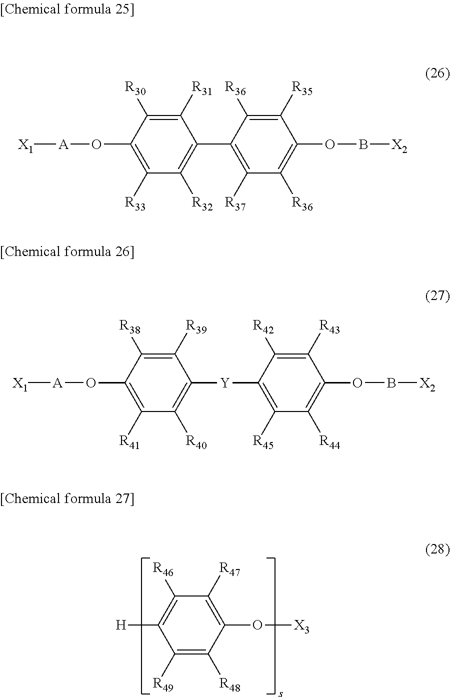

In Formulas (26) to (28), R₃₀ to R₃₇, R₃₈ to R₄₅ and R₄₆ to R₄₉ are independent of each other. In other words, R₃₀ to R₃₇, R₃₈ to R₄₅ and R₄₆ to R₄₉ may be the same group as or different groups from each other. R₃₀ to R₃₇, R₃₈ to R₄₅ and R₄₆ to R₄₉ represent a hydrogen atom, an alkyl group, an alkenyl group, an alkynyl group, a formyl group, an alkylcarbonyl group, an alkenylcarbonyl group, or an alkynylcarbonyl group.

In Formula (28), s represents an integer 1 to 100.

Specific examples of the respective functional groups mentioned above as R₃₀ to R₃₇, R₃₈ to R₄₅ and R₄₆ to R₄₉ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited, but for example, an alkenyl group having 2 to 18 carbon atoms is preferable, and an alkenyl group having 2 to 10 carbon atoms is more preferable. Specific examples thereof include a vinyl group, an allyl group, and a 3-butenyl group.

The alkynyl group is not particularly limited, but for example, an alkynyl group having 2 to 18 carbon atoms is preferable, and an alkynyl group having 2 to 10 carbon atoms is more preferable. Specific examples thereof include an ethynyl group and a prop-2-yn-1-yl group (propargyl group).

The alkylcarbonyl group is not particularly limited as long as it is a carbonyl group substituted with an alkyl group, but for example, an alkylcarbonyl group having 2 to 18 carbon atoms is preferable, and an alkylcarbonyl group having 2 to 10 carbon atoms is more preferable. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group, but for example, an alkenylcarbonyl group having 3 to 18 carbon atoms is preferable, and an alkenylcarbonyl group having 3 to 10 carbon atoms is more preferable. Specific examples thereof include an acryloyl group, a methacryloyl group, and a crotonoyl group.

The alkynylcarbonyl group is not particularly limited as long as it is a carbonyl group substituted with an alkynyl group, but for example, an alkynylcarbonyl group having 3 to 18 carbon atoms is preferable, and an alkynylcarbonyl group having 3 to 10 carbon atoms is more preferable. Specific examples thereof include a propioloyl group.

A and B in Formulas (26) and (27) represent a repeating unit represented by the following Formula (29) and a repeating unit represented by the following Formula (30), respectively. In Formula (27), Y represents a linear, branched, or cyclic hydrocarbon having 20 or less carbon atoms.

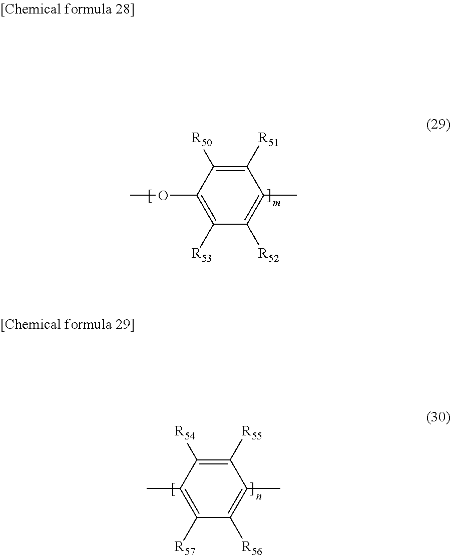

In Formulas (29) and (30), m and n each represent 0 to 20. In addition, it is preferable that m and n represent numerical values so that the sum of m and n is 1 to 30. Hence, it is more preferable that m represents 0 to 20, n represents 0 to 20, and the sum of m and n represents 1 to 30.

In Formulas (29) and (30), R₅₀ to R₅₃ and R₅₄ to R₅₇ are independent of each other, and R₅₀ to R₅₃ and R₅₄ to R₅₇ may be the same group as or different groups from each other, and represent a hydrogen atom, an alkyl group, an alkenyl group, an alkynyl group, a formyl group, an alkylcarbonyl group, an alkynylcarbonyl group, or an alkynylcarbonyl group.

In Formula (27), Y represents a linear, branched, or cyclic hydrocarbon having 20 or less carbon atoms as described above. Examples of Y include a group represented by the following Formula (31).

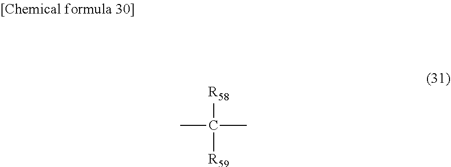

In Formula (31), R₅₈ and R₅₉ each independently represent a hydrogen atom or an alkyl group. Examples of the alkyl group include a methyl group. Examples of the group represented by Formula (31) include a methylene group, a methylmethylene group, and a dimethylmethylene group. Among these, a dimethylmethylene group is preferable.

In Formulas (26) to (28), X₁ to X₃ each independently represent the substituent represented by Formula (4) and/or the substituent represented by Formula (23). In the modified polyphenylene ether compounds represented by Formulas (26) to (28), X₁ to X₃ may be the same substituent as or different substituents from each other.

More specific examples of the modified polyphenylene ether compound represented by Formula (26) include a modified polyphenylene ether compound represented by the following Formula (32).

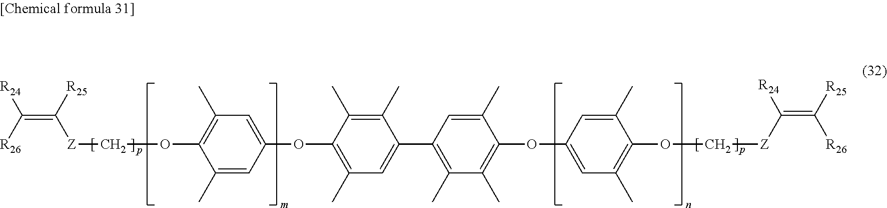

More specific examples of the modified polyphenylene ether compound represented by Formula (26) include a modified polyphenylene ether compound represented by the following Formula (33) and a modified polyphenylene ether compound represented by the following Formula (34).

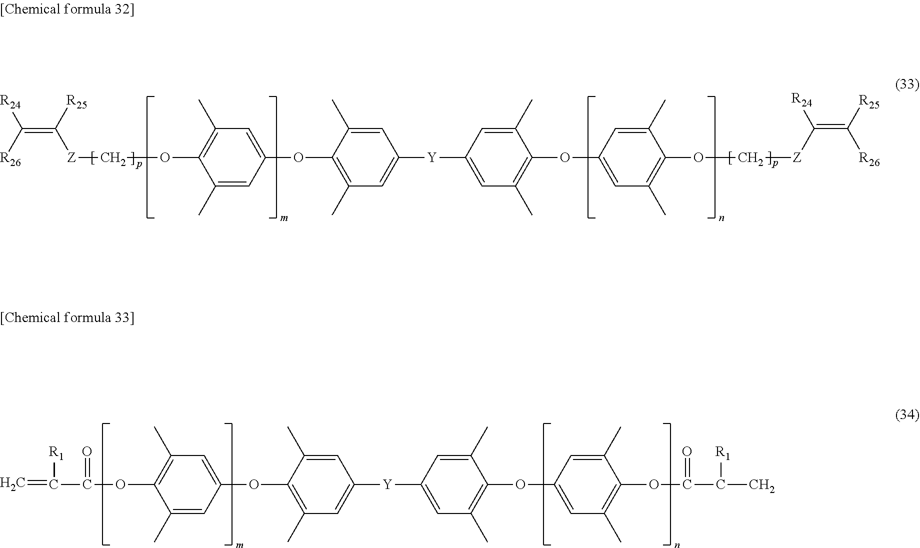

In Formulas (32) to (34), m and n are synonymous with m and n in Formulas (29) and (30). In Formulas (32) and (33), R₂₄ to R₂₆, p, and Z are the same as R₂₄ to R₂₆, p, and Z in Formula (23), respectively. In Formulas (33) and (34), Y is the same as Y in the above (27). In Formula (34), R₁ is the same as R₁ in Formula (4). From the viewpoint of attaining a high Tg more reliably, the modified polyphenylene ether compounds represented by Formulas (32) to (34) preferably have a group represented by Formula (4) at the terminal.

Examples of the method for synthesizing the polyphenylene ether compound used in the present embodiment include a method in which a polyphenylene ether compound of which the terminal is modified with a group represented by Formula (4) and/or a group represented by Formula (23) is synthesized. More specific examples thereof include a method in which polyphenylene ether is reacted with a compound in which a substituent having a carbon-carbon unsaturated double bond is bonded to a halogen atom.

Examples of the compound in which a substituent having a carbon-carbon unsaturated double bond is bonded to a halogen atom include compounds in which the substituents represented by Formulas (4), (23), and (24) are bonded to a halogen atom. Specific examples of the halogen atom include a chlorine atom, a bromine atom, an iodine atom, and a fluorine atom. Among these, a chlorine atom is preferable. More specific examples of the compound in which a substituent having a carbon-carbon unsaturated double bond is bonded to a halogen atom include p-chloromethylstyrene and m-chloromethylstyrene.

Polyphenylene ether which is a raw material is not particularly limited as long as a predetermined modified polyphenylene ether compound can be finally synthesized. Specific examples thereof include those containing polyphenylene ether containing 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the polyphenylene ether compound of the present embodiment include the methods described above. Specifically, polyphenylene ether as described above and a compound in which a substituent having a carbon-carbon unsaturated double bond is bonded to a halogen atom are dissolved in a solvent and stirred. By doing so, polyphenylene ether reacts with the compound in which a substituent having a carbon-carbon unsaturated double bond is bonded to a halogen atom, and the polyphenylene ether compound used in the present embodiment is obtained.

The reaction is preferably conducted in the presence of an alkali metal hydroxide. By doing so, it is considered that this reaction suitably proceeds. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and by doing so, the substituent having a carbon-carbon unsaturated double bond is bonded to the oxygen atom of the phenol group instead of the hydrogen atom of the phenol group in the polyphenylene ether.

The alkali metal hydroxide is not particularly limited as long as it can act as a dehalogenating agent, and examples thereof include sodium hydroxide. In addition, the alkali metal hydroxide is usually used in the form of an aqueous solution and is specifically used as an aqueous sodium hydroxide solution.

The reaction conditions such as reaction time and reaction temperature also vary depending on the compound in which a substituent having a carbon-carbon unsaturated double bond is bonded to a halogen atom and the like, and are not particularly limited as long as they are conditions under which the reaction as described above suitably proceeds. Specifically, the reaction temperature is preferably room temperature to 100° C. and more preferably 30° C. to 100° C. In addition, the reaction time is preferably 0.5 to 20 hours and more preferably 0.5 to 10 hours.

The solvent used at the time of the reaction is not particularly limited as long as it can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples thereof include toluene.

The above reaction is preferably conducted in the presence of not only an alkali metal hydroxide but also a phase transfer catalyst. In other words, the above reaction is preferably conducted in the presence of an alkali metal hydroxide and a phase transfer catalyst. By doing so, it is considered that the above reaction more suitably proceeds. This is considered to be due to the following. This is considered to be because the phase transfer catalyst is a catalyst which has a function of taking in the alkali metal hydroxide, is soluble in both phases of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is incompatible with water is used as a solvent, it is considered that when the aqueous sodium hydroxide solution is dropped into the solvent subjected to the reaction as well, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, when the reaction is conducted in the presence of an alkali metal hydroxide and a phase transfer catalyst, it is considered that the above reaction more suitably proceeds.

The phase transfer catalyst is not particularly limited, and examples thereof include quaternary ammonium salts such as tetra-n-butylammonium bromide.

The resin composition used in the present embodiment preferably contains a modified polyphenylene ether compound obtained as described above as a radical polymerizable compound.

The resin composition according to the present embodiment may contain compounds as exemplified below as a radical polymerizable compound.

Specific examples thereof include a compound having an acryloyl group in the molecule, a compound having a methacryloyl group in the molecule, a compound having a vinyl group in the molecule, a compound having an allyl group in the molecule, a compound having an acenaphthylene structure in the molecule, a compound having a maleimide group in the molecule, and an isocyanurate compound having an isocyanurate group in the molecule.

The compound having an acryloyl group in the molecule is an acrylate compound. Examples of the acrylate compound include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The compound having a methacryloyl group in the molecule is a methacrylate compound. Examples of the methacrylate compound include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate and trimethacrylate compounds such as trimethylolpropane trimethacrylate.

The compound having a vinyl group in the molecule is a vinyl compound. Examples of the vinyl compound include a monofunctional vinyl compound (monovinyl compound) having one vinyl group in the molecule and a polyfunctional vinyl compound having two or more vinyl groups in the molecule. Examples of the polyfunctional vinyl compound include divinylbenzene and polybutadiene.

The compound having an allyl group in the molecule is an allyl compound. Examples of the allyl compound include a monofunctional allyl compound having one allyl group in the molecule and a polyfunctional allyl compound having two or more allyl groups in the molecule. Examples of the polyfunctional allyl compound include triallyl isocyanurate compounds such as triallyl isocyanurate (TAIC), diallyl bisphenol compounds, and diallyl phthalate (DAP).

The compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkylacenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The compound having a maleimide group in the molecule is a maleimide compound. Examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

The compound having an isocyanurate group in the molecule is an isocyanurate compound. Examples of the isocyanurate compound include a compound having an alkenyl group in the molecule (alkenyl isocyanurate compound), and examples thereof include a trialkenyl isocyanurate compound such as triallyl isocyanurate (TAIC).

Among these, an allyl compound, a vinyl compound, a maleimide compound and the like are suitably exemplified as a radical polymerizable compound other than the modified polyphenylene ether compound described above.

The radical polymerizable compound may be used singly or in combination of two or more kinds thereof.

In a case where two or more kinds are combined, it is preferable to contain one or more of the terminal modified polyphenylene ether compounds described above and further, for example, an allyl compound having an allyl group in the molecule as described above. As the allyl compound, an allyl isocyanurate compound having two or more allyl groups in the molecule is preferable, and triallyl isocyanurate (TAIL) is more preferable. Therefore, in a case where the terminal modified polyphenylene ether and triallyl isocyanurate undergo a radical reaction, there is an advantage that the obtained resin cured product exhibits high heat resistance.

(Free Radical Compound)

The free radical compound used in the present embodiment includes at least one selected from the group consisting of a compound (A) represented by the following Formula (1), a compound (B) represented by the following Formula (2), and a compound (C) having two or more of at least one group selected from groups represented by the following Formulas (3-1) and (3-2). By containing such a free radical compound, it is considered that the resin composition of the present embodiment can exert excellent moldability (resin flowability capable of filling the circuit pattern, namely, circuit filling properties) while exhibiting properties such as low dielectric properties and a high Tg.

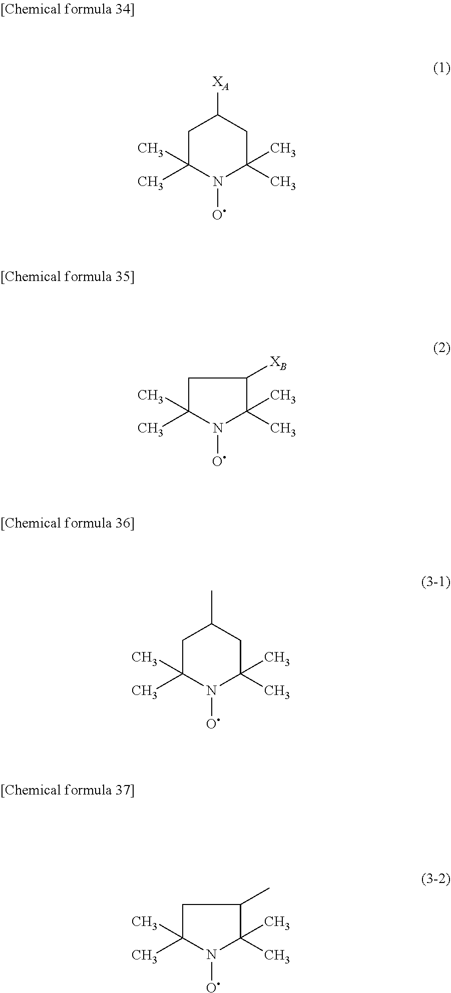

In Formulas (1) and (2), X_{A} and X_{B} each independently represent a hydrogen atom, an amino group, a cyano group, a hydroxy group, an isothiocyanate, a methoxy group, a carboxy group, a carbonyl group, an amide group, or a benzoyloxy group.

The compound (C) having two or more of at least one group selected from groups represented by Formulas (3-1) and (3-2) is not particularly limited, and may be a compound having both of the groups represented by Formulas (3-1) and (3-2), a compound having two or more of the group represented by Formula (3-1), or a compound having two or more of the group represented by Formula (3-2). Specific examples of the compound (C) include a compound represented by the following Formula (3-3).

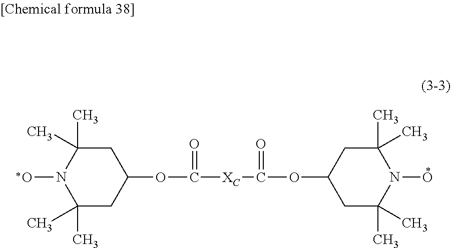

In Formula (3-3), X_{C} represents an alkylene group, an aromatic structure, a carbonyl group, an amide group or an ether bond.

More specific examples of these include, for example, 4-acetamide, 4-glycidyloxy, 4-benzoyloxy, 4-(2-iodoacetamide), 4-[2-[2-(4-iodophenoxy)ethoxy]carbonyl]benzoyloxy, 4-methacryloyloxy, 4-oxo, and 4-propargyloxy.

More specific examples of the free radical compound that is preferably used in the present embodiment include 4-amino-2,2,6,6-tetramethylpiperidine 1-oxyl free radical, 4-acetamide-2,2,6,6-tetramethylpiperidine 1-oxyl free radical, 4-carboxy-2,2,6,6-tetramethylpiperidine 1-oxyl free radical, 4-cyano-2,2,6,6-tetramethylpiperidine 1-oxyl free radical, 4-glycidyloxy-2,2,6,6-tetramethylpiperidine 1-oxyl-free radical, 4-hydroxy-2,2,6,6-tetramethylpiperidine 1-oxyl-free radical, 4-hydroxy-2,2,6,6-tetramethylpiperidine 1-oxylbenzoate free radical, 4-isothiocyanato-2,2,6,6-tetramethylpiperidine 1-oxyl free radical, 4-(2-iodoacetamido)-2,2,6,6-tetramethylpiperidine 1-oxyl free radical, 4-[2-[2-(4-iodophenoxy)ethoxy]carbonyl]benzoyloxy-2,2,6,6-tetramethylpiperidine-1-oxyl free radical, 4-methoxy-2,2,6,6-tetramethylpiperidine 1-oxyl free radical, 4-methacryloyloxy-2,2,6,6-tetramethylpiperidine 1-oxyl free radical, 4-oxo-2,2,6,6-tetramethylpiperidine 1-oxyl free radical, 2,2,6,6-tetramethylpiperidine 1-oxyl free radical, 2,2,6,6-tetramethyl-4-(2-propinyloxy)piperidine 1-oxyl free radical, bis(2,2,6,6-tetramethyl-4-piperidyl-1-oxyl) sebacate, 3-carboxy-2,2,5,5-tetramethylpyrrolidine 1-oxyl free radical, and 4-(2-chloroacetamide)-2,2,6,6-tetramethylpiperidine 1-oxyl free radical.

Various free radical compounds have been mentioned above, and these may be used singly or in combination of two or more kinds thereof.

As the free radical compounds as described above of the present embodiment, commercially available ones can also be used, and are available from, for example, Tokyo Chemical Industry Co., Ltd.

(Inorganic Filler)

The resin composition according to the present embodiment may further contain an inorganic filler. The inorganic filler is not particularly limited and includes those added to enhance the heat resistance and flame retardancy of the cured product of a resin composition. By containing an inorganic filler, it is considered that heat resistance, flame retardancy and the like can be further enhanced as well as an increase in the coefficient of thermal expansion can be suppressed.

Specific examples of the inorganic filler that can be used in the present embodiment include silica such as spherical silica, metal oxides such as alumina, titanium oxide, and mica, metal hydroxides such as aluminum hydroxide and magnesium hydroxide, talc, aluminum borate, barium sulfate, and calcium carbonate. Among these, silica, mica and talc are preferable and spherical silica is more preferable. The inorganic filler may be used singly or in combination of two or more kinds thereof. An inorganic filler as described above may be used as it is, but one subjected to a surface treatment with an epoxysilane-type, vinylsilane-type, methacrylsilane-type, or phenylaminosilane-type silane coupling agent may be used. The silane coupling agent can be used by being added to the filler by an integral blend method instead of the method of being used in the surface treatment of the filler in advance.

(Reaction Initiator)

The resin composition according to the present embodiment may contain a reaction initiator (initiator) as described above. The curing reaction can proceed even though the resin composition does not contain a reaction initiator particularly. However, a reaction initiator may be added since there is a case where it is difficult to raise the temperature until curing proceeds depending on the process conditions.

The reaction initiator is not particularly limited as long as it can promote the curing reaction of the resin composition. Specific examples thereof include a metal oxide, an azo compound, and a peroxide.

Specific examples of the metal oxide include metal salts of carboxylic acids.

Examples of the peroxide include α,α′-di(t-butylperoxy)diisopropylbenzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile.

Specific examples of the azo compound include 2,2′-azobis(2,4,4-trimethylpentane), 2,21-azobis(N-butyl-2-methylpropionamide), and 2,2′-azobis(2-methylbutyronitrile).

Among these, α,α′-di(t-butylperoxy)diisopropylbenzene is preferably used as a preferable reaction initiator. α,α-Di(t-butylperoxy)diisopropylbenzene exhibits low volatility, thus does not volatilize at the time of drying and storage, and exhibits favorable stability. α,α′-Di(t-butylperoxy)diisopropylbenzene has a relatively high reaction initiation temperature and thus can suppress the promotion of the curing reaction at the time point at which curing is not required, for example, at the time of prepreg drying. By suppressing the curing reaction, it is possible to suppress a decrease in storage stability of the resin composition.

The reaction initiators as described above may be used singly or in combination of two or more kinds thereof.

(Content of Each Component)

The content of the free radical compound is preferably 0.001 to 1 part by mass, more preferably 0.001 to 0.5 parts by mass, still more preferably 0.001 to 0.2 parts by mass with respect to 100 parts by mass of the sum of the styrenic block copolymer and the radical polymerizable compound in the resin composition. When the content of the free radical compound is in the above range, it is considered that a resin composition, which affords a cured product exhibiting low dielectric properties, a high Tg, and a low coefficient of thermal expansion and exhibits excellent moldability, is obtained more reliably.

The content of the styrenic block copolymer is preferably 10 to 60 parts by mass, more preferably 15 to 50 parts by mass, still more preferably 20 to 40 parts by mass with respect to 100 parts by mass of the resin components (organic components) in the resin composition. In other words, the content percentage of the styrenic block copolymer is preferably 10% to 60% by mass with respect to the components other than the inorganic filler (inorganic component) in the resin composition.

The content of the radical polymerizable compound is preferably 30 to 90 parts by mass, more preferably 40 to 80 parts by mass, still more preferably 50 to 70 parts by mass with respect to 100 parts by mass of the resin components (organic components) in the resin composition. In other words, the content percentage of the radical polymerizable compound is preferably 30% to 90% by mass with respect to the components other than the inorganic filler (inorganic component) in the resin composition.

Particularly in the case of containing the radical polymerizable compounds (modified polyphenylene ether compounds) of the preferred embodiment, the content of these preferred radical polymerizable compounds is preferably 10 to 50 parts by mass, more preferably 20 to 50 parts by mass, still more preferably 30 to 40 parts by mass with respect to 100 parts by mass of the resin components (organic components) in the resin composition.

Furthermore, in the case of containing radical polymerizable compounds (allyl compounds and the like) other than the above as a radical polymerizable compound, the content of these other radical polymerizable compounds is preferably 10 to 50 parts by mass, more preferably 20 to 40 parts by mass with respect to 100 parts by mass of the resin components (organic components) in the resin composition.

In a case where the resin composition of the present embodiment contains the reaction initiator, the content of the reaction initiator is not particularly limited, but is, for example, preferably 0.01 to 10 parts by mass, more preferably 0.01 to 5 parts by mass, still more preferably 0.1 to 3 parts by mass with respect to 100 parts by mass of the resin components (organic components) in the resin composition. When the content of the reaction initiator is too low, the curing reaction of the resin composition tends not to start suitably. When the content of the initiator is too high, the dielectric loss tangent of the cured product of the prepreg obtained becomes large and excellent low dielectric properties tend to be unlikely exerted. Hence, when the content of the reaction initiator is in the above range, a cured product of a prepreg exhibiting excellent low dielectric properties is obtained.

In a case where the resin composition of the present embodiment contains the reaction initiator, the proportion of the free radical compound to the reaction initiator in the resin composition is that free radical compound:reaction initiator is preferably about 0.001:1.0 to 0.1:1.0, more preferably about 0.005:1.0 to 0.1:1.0, still more preferably about 0.01:1.0 to 0.1:1.0. It is considered that the effects of the present invention can be thus more reliably attained.

When the resin composition of the present embodiment contains an inorganic filler, the content percentage of the inorganic filler (filler content) is preferably 30% to 300% by mass, more preferably 50% to 200% by mass with respect to the entire resin composition.

<Other Components>

The resin composition according to the present embodiment may contain components (other components) other than the components described above if necessary as long as the effects of the present invention are not impaired. As other components contained in the resin composition according to the present embodiment, for example, additives such as a curing agent, a silane coupling agent, a flame retardant, an antifoaming agent, an antioxidant, a heat stabilizer, an antistatic agent, an ultraviolet absorber, a dye or a pigment, a dispersant, and a lubricant may be further contained. The resin composition of the present embodiment may contain thermosetting resins such as an epoxy resin and a phenol resin other than the polyphenylene ether compound, the allyl compound, and the styrenic block copolymer.

(Prepreg, film with resin, metal-clad laminate, wiring board, and metal foil with resin)

Next, a prepreg for wiring board, a metal-clad laminate, a wiring board, and a metal foil with resin obtained using the resin composition of the present embodiment will be described.

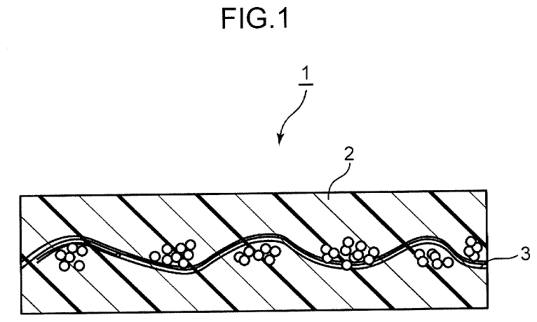

FIG. 1 is a schematic sectional view illustrating an example of a prepreg 1 according to an embodiment of the present invention. In the following description, the reference numerals denote: 1 prepreg, 2 resin composition or semi-cured product of resin composition, 3 fibrous base material, 11 metal-clad laminate, 12 insulating layer, 13 metal foil, 14 wiring, 21 wiring board, 31 metal foil with resin, 32 and 42 resin layer, 41 film with resin, and 43 support film, respectively.

The prepreg 1 according to the present embodiment includes the resin composition containing the thermally expandable microcapsules or a semi-cured product 2 of the resin composition; and a fibrous base material 3 as illustrated in FIG. 1. The prepreg 1 includes one in which the fibrous base material 3 is present in the resin composition or semi-cured product 2 thereof. In other words, the prepreg 1 includes the resin composition or semi-cured product thereof; and the fibrous base material 3 present in the resin composition or semi-cured product 2 thereof.

In the present embodiment, the “semi-cured product” is one in a state in which the resin composition is partly cured so as to be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material, or may be a prepreg including the resin composition before curing (the resin composition in A stage) and a fibrous base material. Specific examples of the prepreg include those in which a fibrous base material is present in the resin composition. The resin composition or semi-cured product thereof may be one obtained by heating and drying the resin composition.

When the prepreg and the metal foil with resin, metal-clad laminate and the like to be described later are fabricated, the resin composition according to the present embodiment is often prepared in the form of a varnish and used as a resin varnish. Such a resin varnish is prepared, for example, as follows.

First, the respective components that can be dissolved in an organic solvent, such as a resin component and a reaction initiator, are put into an organic solvent and dissolved. At this time, heating may be performed if necessary. Thereafter, an inorganic filler and the like, which are components that do not dissolve in an organic solvent, are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the styrenic block copolymer, the radical polymerizable compound and the like, and does not inhibit the curing reaction. Specific examples thereof include toluene, methyl ethyl ketone, cyclohexanone and propylene glycol monomethyl ether acetate. These may be used singly or two or more kinds thereof may be used concurrently.

Examples of the method for fabricating the prepreg 1 of the present embodiment using the varnish-like resin composition of the present embodiment include a method in which the fibrous base material 3 is impregnated with the resin composition 2 in the form of a resin varnish and then drying is performed.

Specific examples of the fibrous base material used in fabrication of the prepreg include glass cloth, aramid cloth, polyester cloth, LCP (liquid crystal polymer) nonwoven fabric, glass nonwoven fabric, aramid nonwoven fabric, polyester nonwoven fabric, pulp paper, and linter paper. When glass cloth is used, a laminate exhibiting excellent mechanical strength is obtained, and glass cloth subjected to flattening is particularly preferable. The glass cloth used in the present embodiment is not particularly limited, but examples thereof include glass cloth with low dielectric constant such as E glass, S glass, NE glass, Q glass, L glass, L2 glass, and T glass. Specifically, the flattening can be carried out, for example, by continuously pressing the glass cloth with press rolls at an appropriate pressure to flatten the yarn. As for the thickness of the fibrous base material, for example, a fibrous base material having a thickness of 0.01 to 0.3 mm can be generally used.

Impregnation of the fibrous base material 3 with the resin varnish (resin composition 2) is performed by dipping, coating, or the like. This impregnation can be repeated multiple times if necessary. At this time, it is also possible to repeat impregnation using a plurality of resin varnishes having different compositions and concentrations, and adjust the composition (content ratio) and resin amount to the finally desired values.

The fibrous base material 3 impregnated with the resin varnish (resin composition 2) is heated under desired heating conditions, for example, at 80° C. or more and 180° C. or less for 1 minute or more and 10 minutes or less. By heating, the solvent is volatilized from the varnish and the solvent is diminished or removed to obtain the prepreg 1 before curing (in A stage) or in a semi-cured state (B stage).

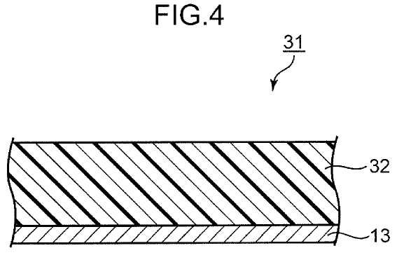

As illustrated in FIG. 4, a metal foil with resin 31 of the present embodiment has a configuration in which a resin layer 32 containing the resin composition described above or a semi-cured product of the resin composition; and a metal foil 13 are laminated. In other words, the metal foil with resin of the present embodiment may be a metal foil with resin including a resin layer containing the resin composition before curing (the resin composition in A stage) and a metal foil, or may be a metal foil with resin including a resin layer containing a semi-cured product of the resin composition (the resin composition in B stage) and a metal foil.

Examples of the method for fabricating such a metal foil with resin 31 include a method in which a resin composition in the form of a resin varnish as described above is applied to the surface of the metal foil 13 such as a copper foil and then dried. Examples of the coating method include a bar coater, a comma coater, a die coater, a roll coater, and a gravure coater.

As the metal foil 13, metal foils used in metal-clad laminates, wiring boards and the like can be used without limitation, and examples thereof include copper foil and aluminum foil.

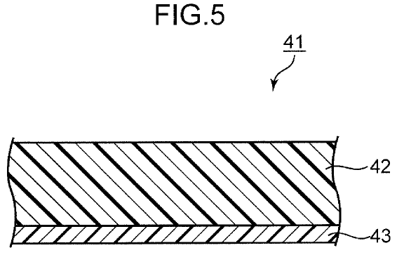

As illustrated in FIG. 5, a film with resin 41 of the present embodiment has a configuration in which a resin layer 42 containing the resin composition described above or a semi-cured product of the resin composition; and a film supporting substrate 43 are laminated. In other words, the film with resin of the present embodiment may be a film with resin including the resin composition before curing (the resin composition in A stage); and a film supporting substrate, or may be a film with resin including a semi-cured product of the resin composition (the resin composition in B stage); and a film supporting substrate.

As the method for fabricating such a film with resin 41, for example, a resin composition in the form of a resin varnish as described above is applied to the surface of the film supporting substrate 43, and then the solvent is volatilized from the varnish and diminished or removed, whereby a film with resin before curing (A stage) or in a semi-cured state (B stage) can be obtained.

Examples of the film supporting substrate include electrical insulating films such as a polyimide film, a PET (polyethylene terephthalate) film, a polyester film, a poly(parabanic acid) film, a polyether ether ketone film, a polyphenylene sulfide film, an aramid film, a polycarbonate film, and a polyarylate film.

In the film with resin and metal foil with resin of the present embodiment, the resin composition or semi-cured product thereof may be one obtained by drying or heating and drying the resin composition as in the prepreg described above.

The thickness and the like of the metal foil 13 and the film supporting substrate 43 can be appropriately set depending on the desired purpose. For example, as the metal foil 13, a metal foil having a thickness of about 0.2 to 70 μm can be used. In a case where the thickness of metal foil is, for example, 10 μm or less, the metal foil may be a carrier-attached copper foil including a release layer and a carrier in order to improve handleability. The application of the resin varnish to the metal foil 13 and the film supporting substrate 43 is performed by coating or the like, and this can be repeated multiple times if necessary. At this time, it is also possible to repeat coating using a plurality of resin varnishes having different compositions and concentrations, and adjust the composition (content ratio) and resin amount to the finally desired values.

Drying or heating and drying conditions in the fabrication method of the metal foil with resin 31 and the resin film 41 are not particularly limited, but a resin composition in the form of a resin varnish is applied to the metal foil 13 and the film supporting substrate 43, and then heating is performed under desired heating conditions, for example, at 50° C. to 170° C. for about 0.5 to 10 minutes to volatilize the solvent from the varnish and diminish or remove the solvent, whereby the metal foil with resin 31 and resin film 41 before curing (A stage) or in a semi-cured state (B stage) are obtained.

The metal foil with resin 31 and resin film 41 may include a cover film and the like if necessary. By including a cover film, it is possible to prevent foreign matter from entering. The cover film is not particularly limited as long as it can be peeled off without damaging the form of the resin composition, and for example, a polyolefin film, a polyester film, a TPX film, films formed by providing a mold releasing agent layer on these films, and paper obtained by laminating these films on a paper substrate can be used.

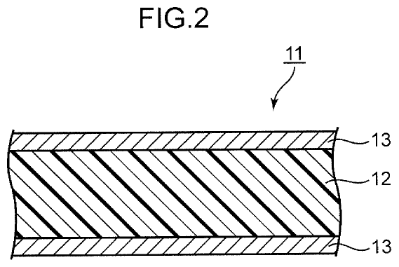

As illustrated in FIG. 2, a metal-clad laminate 11 of the present embodiment includes an insulating layer 12 containing a cured product of the resin composition described above or a cured product of the prepreg described above; and a metal foil 13. As the metal foil 13 used in the metal-clad laminate 11, a metal foil similar to the metal foil 13 described above can be used.

The metal-clad laminate 11 of the present embodiment can also be fabricated using the metal foil with resin 31 or resin film 41 described above.

As the method for fabricating a metal-clad laminate using the prepreg 1, metal foil with resin 31, or resin film 41 obtained in the manner described above, one or a plurality of prepregs 1, metal foils with resin 31, or resin films 41 are superimposed on one another, and the metal foils 13 such as copper foil are further superimposed on both upper and lower sides or on one side, and this is laminated and integrated by heating and pressing, whereby a double-sided metal-clad or single-sided metal-clad laminate can be fabricated. The heating and pressing conditions can be appropriately set depending on the thickness of the laminate to be fabricated, the kind of the resin composition, and the like, but for example, the temperature may be set to 170° C. to 230° C., the pressure may be set to 0.5 to 5.0 MPa, and the time may be set to 60 to 150 minutes.

The metal-clad laminate 11 may be fabricated by forming a film-like resin composition on the metal foil 13 without using the prepreg 1 or the like and performing heating and pressing.

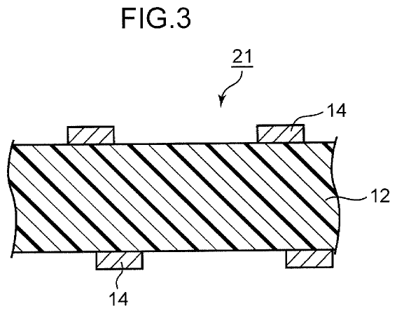

As illustrated in FIG. 3, a wiring board 21 of the present embodiment includes wiring 14 and an insulating layer 12 containing a cured product of the resin composition described above or a cured product of the prepreg described above.

The resin composition of the present embodiment is suitably used as a material for an insulating layer of a wiring board. As the method for fabricating the wiring board 21, for example, the metal foil 13 on the surface of the metal-clad laminate 13 obtained above is etched to form a circuit (wiring), whereby the wiring board 21 having a conductor pattern (wiring 14) provided as a circuit on the surface of a laminate can be obtained. Examples of the circuit forming method include circuit formation by a semi additive process (SAP) or a modified semi additive process (MSAP) in addition to the method described above.

The prepreg, film with resin, and metal foil with resin obtained using the resin composition of the present embodiment are extremely useful in industrial applications since the cured products thereof exhibit low dielectric properties, a low coefficient of thermal expansion, and a high Tg as well as excellent moldability (circuit filling properties). The metal-clad laminate and wiring board obtained by curing these have the advantages of low dielectric properties, high Tg, and excellent handleability.

Hereinafter, the present invention will be described more specifically with reference to Examples, but the scope of the present invention is not limited to these.

### EXAMPLES

First, the components used in the preparation of resin compositions in the present Example will be described.

(Styrenic Block Copolymer)

Styrenic block copolymer 1: Styrene isoprene styrene copolymer (SEPTON 2063 manufactured by Kuraray Co., Ltd., durometer hardness: 36, content of structural unit derived from styrene: 13% by mass, weight average molecular weight: 95,000)

Styrenic block copolymer 2: Hydrogenated styrene (ethylene/butylene) styrene copolymer (Tuftec H1052 manufactured by Asahi Kasei Corporation, durometer hardness: 67, content of structural unit derived from styrene: 20% by mass, weight average molecular weight: 91000)

Styrenic block copolymer 3: Hydrogenated methylstyrene (ethylene/butylene) methylstyrene copolymer (SEPTON V9827 manufactured by Kuraray Co., Ltd., durometer hardness: 78, content of structural unit derived from styrene: 30% by mass, weight average molecular weight: 92000)

Styrenic block copolymer 4: Hydrogenated styrene (ethylene/butylene) styrene copolymer (Dynaron 9901P manufactured by JSR Corporation, durometer hardness: 98, content of structural unit derived from styrene: 53% by mass, weight average molecular weight: 100,000)

(Radical polymerizable compound: Polyphenylene ether compound)
PPE1: Modified polyphenylene ether obtained by modifying terminal hydroxyl group of polyphenylene ether with methacryloyl group (a modified polyphenylene ether compound represented by Formula (34), where Y is a dimethylmethylene group (a group represented by Formula (31), where R₅₈ and R₅₉ are a methyl group), SA9000 manufactured by SABIC Innovative Plastics Co., Ltd., weight average molecular weight Mw: 2000, number of terminal functional groups: 2)
PPE2: Polyphenylene ether compound having vinylbenzyl group (ethenylbenzyl group) at terminal (OPE-2st 1200 manufactured by MITSUBISHI GAS CHEMICAL COMPANY, a polyphenylene ether compound, which has Mn of 1200 and is represented by Formula (32), where Z is a phenylene group, R₂₄ to R₂₆ are a hydrogen atom, and p is 1)

(Radical Polymerizable Compound: Allyl Compound)
TAIC: Triallyl isocyanurate (manufactured by Nihon Kasei Co., Ltd.)

(Free Radical Compound)

Free radical compound 1: 4-Benzoyloxy-tempo, a free radical compound represented by the following formula (“110878” manufactured by Tokyo Chemical Industry Co., Ltd.)

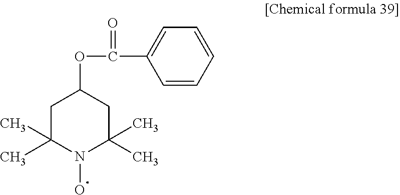

Free radical compound 2: Bis-tempo sebacate, a free radical compound represented by the following formula (“B5642” manufactured by Tokyo Chemical Industry Co., Ltd.)

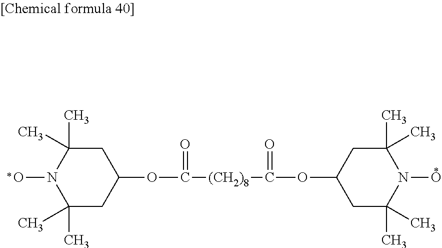

Free radical compound 3: Tempo, a free radical compound represented by the following formula (“T3751” manufactured by Tokyo Chemical Industry Co., Ltd.)

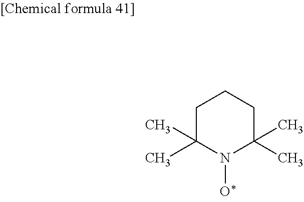

Free radical compound 4: 4H-tempo, a free radical compound represented by the following formula (“H0865” manufactured by Tokyo Chemical Industry Co., Ltd.)

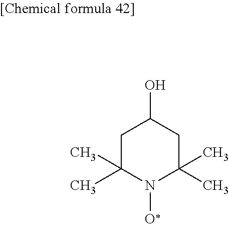

(Polymerization Inhibitor)

Hydroquinone HQ: Hydroquinone (manufactured by Tokyo Chemical Industry Co., Ltd.)

(Reaction Initiator)
Peroxide: “PERBUTYL P”, 1,3-bis(butylperoxyisopropyl)benzene (manufactured by NOF CORPORATION)

(Inorganic Filler)

Silica particles: “SC2300-SVJ” vinylsilane treated spherical silica (manufactured by ADMATECHS COMPANY LIMITED)

### Examples 1 to 13 and Comparative Examples 1 to 3

[Preparation Method]

(Resin Varnish)

First, the respective components other than the inorganic filler were added to and mixed in toluene at the compositions (parts by mass) presented in Table 1 so that the solid concentration was 50% by mass. The mixture was stirred for 60 minutes. Thereafter, the inorganic filler was added to the obtained liquid and dispersed using a bead mill. By doing so, a varnish-like resin composition (varnish) was obtained.

(Metal Foil with Resin and Evaluation Substrate)

Metal foils with resin were fabricated using the respective resin varnishes of Examples and Comparative Examples prepared above. The obtained varnish was applied to a metal foil (copper foil, 3EC-VLP manufactured by Mitsui Mining & Smelting Co., Ltd., thickness: 12 μm) to have a thickness of 20 μm, and heated at 80° C. for 2 minutes, thereby fabricating a metal foil with resin. Then, two sheets of the obtained metal foil with resin were stacked so that the resin layers were in contact with each other. This as a body to be pressed was heated and pressed at 200° C. and a pressure of 4 MPa in a vacuum for 2 hours to cure the resin layer of the metal foil with resin. This was used as an evaluation substrate (cured product of metal foil with resin). The thickness of the resin layer (thickness other than the metal foil) in the evaluation substrate was 40 μm.

<Evaluation Test>

(Glass Transition Temperature (Tg))

The Tg of the laminate obtained by removing the copper foil from the evaluation substrate (cured product of metal foil with resin) was measured using a viscoelastic spectrometer “DMS100” manufactured by Seiko Instruments Inc. At this time, dynamic viscoelasticity measurement (DMA) was performed with a tensile module at a frequency of 10 Hz, and the temperature at which tan 8 was maximized when the temperature was raised from room temperature to 320° C. at a rate of temperature rise of 5° C./min was taken as Tg. In the present Example, it was evaluated as “excellent” when Tg was 230° C. or more, it was evaluated as “good” when Tg was 200° C. or more, and it was evaluated as “poor” when Tg was less than 200° C.

(Dielectric Properties: Relative Dielectric Constant (Dk))

The relative dielectric constant of the laminate obtained by removing the copper foil from the evaluation substrate (cured product of metal foil with resin) at 10 GHz was measured by the cavity perturbation method. Specifically, the relative dielectric constant (Dk) of the laminate obtained by removing the copper foil from the evaluation substrate at 10 GHz was measured using a network analyzer (N5230A manufactured by Keysight Technologies). In the present Example, it was evaluated as “excellent” when Dk was 2.6 or less, it was evaluated as “good” when Dk was 2.7 or less, and it was evaluated as “poor” when Dk was more than 2.7.

[Coefficient of Linear Thermal Expansion (CTE)]

The coefficient of linear thermal expansion in the planar direction of the laminate obtained by removing the copper foil from the evaluation substrate (cured product of metal foil with resin) was measured in a tensile mode by a method conforming to JIS C 6481. The measurement condition was a rate of temperature rise of 10° C./min, and the temperature range was a temperature range of less than Tg. Specifically, the measurement was performed at 50° C. to 100° C. using a thermomechanical analyzer (TMA) (TMA/SS7000 manufactured by Hitachi High-Tech Corporation). In the present Example, it was evaluated as “excellent” when CTE was 30 ppm or less, it was evaluated as “good” when CTE was 40 ppm or less, and it was evaluated as “poor” when CTE was more than 40 ppm.

(Moldability: Circuit Filling Properties)

A cured product was prepared which had a copper pattern of 250 mm×250 mm having a residual copper rate of 50%, a copper wire thickness of 12 and a copper wire width of 2 μm on a lattice. A 250 mm×250 mm metal foil with resin was placed on both sides thereof so that the resin surface was in contact with the cured product. These were sandwiched between metal plates having a thickness of about 3 mm, and heating and pressing were conducted using a pressing machine for laminating molding under the conditions described below. As the heating conditions, the temperature was raised from 30 degrees to 200 degrees at 6 degrees per minute. As the pressing conditions, the pressure applied to the metal foil with resin was set to 1 MPa at the start of heating, and then the pressure applied to the metal foil with resin was set to 4 MPa when the temperature reached 80° C. to cure the metal foil with resin.

In the present Example, it was evaluated as “good” when a gap was not generated between the lattice pattern and the resin cured product but the resin cured product was filled in the lattice pattern, and it was evaluated as “poor” when a gap was generated. The presence or absence of a gap was determined by whether or not a gap that looked whitish was observed when the copper foil of the cured product fabricated using the pressing machine for laminating molding was removed and light was transmitted from the other surface.

The results are presented in Table 1.

TABLE 1

| | Exam- | Exam- | Exam- | Exam- | Exam- | Exam- | Exam- | Exam- | Exam- |
|---|---|---|---|---|---|---|---|---|---|
| Component composition | ple 1 | ple 2 | ple 3 | ple 4 | ple 5 | ple 6 | ple 7 | ple 8 | ple 9 |
| Styrenic block copolymer 1 | | | | | | | | 30 | |
| Styrenic block copolymer 2 | 30 | 30 | 30 | 30 | 30 | 30 | 30 | | |
| Styrenic block copolymer 3 | | | | | | | | | 30 |
| Styrenic block copolymer 4 | | | | | | | | | |
| Radical polymerizable compound | 35 | 35 | 35 | 35 | 35 | 35 | 35 | 35 | 35 |
| (modified PPE1) | | | | | | | | | |
| Radical polymerizable compound | | | | | | | | | |
| (modified PPE2) | | | | | | | | | |
| Radical polymerizable compound | 35 | 35 | 35 | 35 | 35 | 35 | 35 | 35 | 35 |
| (TAIC) | | | | | | | | | |
| Free radical compound 1 | 0.1 | | | | 0.001 | 1 | 0.1 | 0.1 | 0.1 |
| Free radical compound 2 | | 0.1 | | | | | | | |
| Free radical compound 3 | | | 0.1 | | | | | | |
| Free radical compound 4 | | | | 0.1 | | | | | |
| Polymerization inhibitor | | | | | | | | | |
| Reaction initiator | 1 | 1 | 1 | 1 | 1 | 1 | 3 | 1 | 1 |
| Inorganic filler | 150 | 150 | 150 | 150 | 150 | 150 | 150 | 150 | 150 |
| Evaluated properties | | | | | | | | | |
| Glass transition temperature | 240 | 240 | 235 | 240 | 240 | 200 | 265 | 240 | 240 |
| Relative dielectric constant | 2.6 | 2.6 | 2.6 | 2.6 | 2.6 | 2.6 | 2.6 | 2.55 | 2.63 |
| Coefficient of linear thermal | 33 | 35 | 36 | 35 | 32 | 40 | 30 | 30 | 35 |
| expansion | | | | | | | | | |
| Circuit filling properties | good | good | good | good | good | good | good | good | good |

| | Exam- | Exam- | Exam- | Exam- | Comparative | Comparative | Comparative |
|---|---|---|---|---|---|---|---|
| Component composition | ple 10 | ple 11 | ple 12 | ple 13 | Example 1 | Example 2 | Example 3 |
| Styrenic block copolymer 1 | | | | | | | |
| Styrenic block copolymer 2 | | 30 | 15 | 60 | 30 | 30 | |
| Styrenic block copolymer 3 | | | | | | | |
| Styrenic block copolymer 4 | 30 | | | | | | |
| Radical polymerizable compound | 35 | | 42.5 | 20 | 35 | 35 | 50 |
| (modified PPE1) | | | | | | | |
| Radical polymerizable compound | | 35 | | | | | |
| (modified PPE2) | | | | | | | |
| Radical polymerizable compound | 35 | 35 | 42.5 | 20 | 35 | 35 | 50 |
| (TAIC) | | | | | | | |
| Free radical compound 1 | 0.1 | 0.1 | 0.1 | 0.1 | | | 0.1 |
| Free radical compound 2 | | | | | | | |
| Free radical compound 3 | | | | | | | |
| Free radical compound 4 | | | | | | | |
| Polymerization inhibitor | | | | | | 0.1 | |
| Reaction initiator | 1 | 1 | 1 | 1 | 1 | 1 | 1 |
| Inorganic filler | 150 | 150 | 150 | 150 | 150 | 150 | 150 |
| Evaluated properties | | | | | | | |
| Glass transition temperature | 240 | 230 | 250 | 230 | 240 | 190 | 255 |
| Relative dielectric constant | 2.68 | 2.6 | 2.7 | 2.55 | 2.6 | 2.6 | 3.1 |
| Coefficient of linear thermal | 34 | 36 | 28 | 40 | 36 | 50 | 22 |
| expansion | | | | | | | |
| Circuit filling properties | good | good | good | good | poor | good | good |

(Discussion)

As is apparent from the results presented in Table 1, it was confirmed that a cured product exhibiting excellent circuit filling properties while exhibiting low dielectric properties, a low CTE, and a high Tg in a well-balanced manner is obtained from the resin composition of the present invention.

On the other hand, it was found that sufficient circuit filling properties are not attained in Comparative Example 1 in which the free radical compound according to the present invention is not used. In Comparative Example 2 in which a general polymerization initiator was used instead of the free radical compound, the Tg decreased and the CTE increased. In Comparative Example 3 in which a styrenic block copolymer was not contained, sufficiently low dielectric properties were not attained.

This application is based on Japanese Patent Application No. 2020-157403 filed on Sep. 18, 2020, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

The present invention has a wide range of industrial applicability in the technical field relating to electronic materials and various devices using the same.

1. A resin composition comprising:
a styrenic block copolymer;
a radical polymerizable compound; and
at least one free radical compound selected from the group consisting of a compound (A) represented by the following Formula (1), a compound (B) represented by the following Formula (2), and a compound (C) having two or more of at least one group selected from groups represented by the following Formulas (3-1) and (3-2): 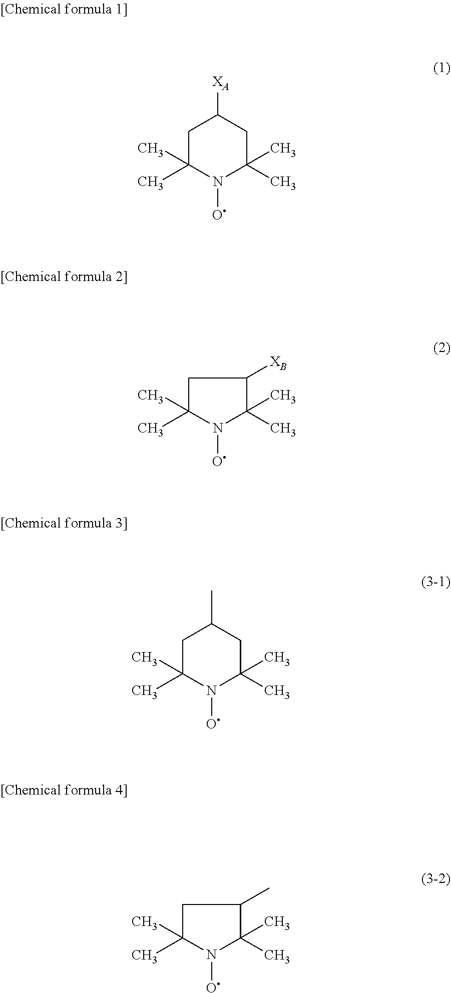
(in Formulas (1) and (2), X_{A} and X_{B} each independently represent a hydrogen atom, an amino group, a cyano group, a hydroxy group, an isothiocyanate, a methoxy group, a carboxy group, a carbonyl group, an amide group, or a benzoyloxy group).

2. The resin composition according to claim 1, wherein a weight average molecular weight of the styrenic block copolymer is 10,000 to 200,000.

3. The resin composition according to claim 1, wherein the styrenic block copolymer includes at least one selected from the group consisting of a methylstyrene (ethylene/butylene) methyl styrene copolymer, a methylstyrene (ethylene-ethylene/propylene) methylstyrene copolymer, a styrene isoprene copolymer, a styrene isoprene styrene copolymer, a styrene (ethylene/butylene) styrene copolymer, a styrene ethylene copolymer, a styrene (ethylene-ethylene/propylene) styrene copolymer, a styrene butadiene styrene copolymer, a styrene (butadiene/butylene) styrene copolymer, a styrene isobutylene styrene copolymer, and hydrogenated products of these copolymers.

4. The resin composition according to claim 1, wherein the radical polymerizable compound includes a polyphenylene ether compound of which a terminal is modified with a substituent having a carbon-carbon unsaturated double bond.

5. The resin composition according to claim 1, wherein
the polyphenylene ether compound has a group represented by the following Formula (4): 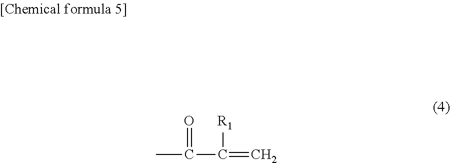
(in Formula (4), R₁ represents a hydrogen atom or an alkyl group).

6. The resin composition according to claim 1, comprising the free radical compound at 0.001 to 1 part by mass with respect to 100 parts by mass of a sum of the styrenic block copolymer and the radical polymerizable compound.

7. The resin composition according to claim 1, further comprising a reaction initiator.

8. The resin composition according to claim 7, wherein a content ratio (mass ratio) of the free radical compound to the reaction initiator is 0.001:1.0 to 0.1:1.0.

9. A prepreg comprising:
the resin composition according to claim 1 or a semi-cured product of the resin composition; and
a fibrous base material.

10. A film with resin comprising:
a resin layer containing the resin composition according to claim 1 or a semi-cured product of the resin composition; and
a support film.

11. A metal foil with resin comprising:
a resin layer containing the resin composition according to claim 1 or a semi-cured product of the resin composition; and
a metal foil.

12. A metal-clad laminate comprising:
an insulating layer containing a cured product of the resin composition according to claim 1; and
a metal foil.

13. A wiring board comprising:
an insulating layer containing a cured product of the resin composition according to claim 1; and
wiring.

14. A metal-clad laminate comprising:
an insulating layer containing a cured product of the prepreg according to claim 9; and
a metal foil.

15. A wiring board comprising:
an insulating layer containing a cured product of the prepreg according to claim 9; and
wiring.
